(19) United States
(12) Patent Application Publication
(10) Pub. No.: US 2026/0273930 A1
(43) Pub. Date: Sep. 17, 2026

(54) APPARATUS AND METHOD FOR MEASURING DROPLET INFORMATION, AND INKJET PRINTING SYSTEM

(71) Applicant: SAMSUNG DISPLAY CO., LTD., YONGIN-SI (KR)

(72) Inventors: Konta YU, Yongin-si (KR); Tomoeda SATOSHI, Yongin-si (KR); Cheong Wan MIN, Yongin-si (KR); Won Joon CHOI, Yongin-si (KR)

(21) Appl. No.: 19/344,668

(22) Filed: Sep. 30, 2025

(30) Foreign Application Priority Data
Mar. 13, 2025 (KR) 10-2025-0032986

(51) Int. Cl. B41J 2/045

(52) U.S. Cl. CPC B41J 2/0456; B41J 2/04561; B41J 2/04586

(57) ABSTRACT

An apparatus for measuring droplet information includes a first light source module configured to emit a first light having a first optical characteristic in an oblique direction with respect to a surface of a substrate on which a droplet is positioned. A second light source module is configured to emit a second light having a second optical characteristic different from the first optical characteristic in a direction perpendicular to the surface of the substrate. A camera is configured to photograph a droplet being illuminated with at least one of the first light and the second light from above the droplet. A control module is configured to analyze at least one image photographed by the camera to acquire droplet information therefrom.

### CROSS-REFERENCE TO RELATED APPLICATION

This application claims priority under 35 U.S.C. § 119 to Korean Patent Application No. 10-2025-0032986 filed Mar. 13, 2025 in the Korean Intellectual Property Office (KIPO), the entire disclosure of which is incorporated by reference herein.

### TECHNICAL FIELD

The present disclosure relates to inkjet deposition and, more specifically, to an apparatus for measuring droplet information, a method for measuring droplet information, and an inkjet printing system using the same.

### BACKGROUND

With the development of multimedia, the importance of display devices is increasing. As the importance of the display devices continues to grow, and as the competition in the display industry intensifies, the demand for cost reduction has also increased. Accordingly, research pertaining to applying inkjet printing techniques to display manufacturing is increasing.

Inkjet printing techniques may be capable of obtaining products with low costs and high quality and such techniques are now being applied to the field of display manufacturing. For example, inkjet printing techniques may be used for disposing color filters, liquid crystal coating, electrode printing, black bezel printing, and the like.

Inkjet printing techniques may also be applied to various processes in the manufacturing of organic light-emitting displays (OLEDs), such as thin film encapsulation (TFE) process, pixel formation process (e.g., a process of forming red, green and blue (RGB) light-emitting layers by inking a polymer material), a process of printing OLED common layers (e.g., a hole injection layer (HIL), a hole transmission layer (HTL)) and the like.

As the application range of the inkjet printing technique expands to various fields, securing the reliability of ink droplets ejected through nozzles has become a concern.

### SUMMARY

An apparatus for measuring droplet information according to an embodiment of the present disclosure includes a first light source module configured to emit a first light having a first optical characteristic, the first light being emitted from the first light source module in an oblique direction with respect to a surface of a substrate on which a droplet is positioned. A second light source module is configured to emit a second light having a second optical characteristic that is different from the first optical characteristic, the second light being emitted from the second source module in a direction perpendicular to the surface of the substrate. A camera is configured to photograph a droplet being illuminated with at least one of the first light and the second light from above the droplet. A control module is configured to analyze at least one image photographed by the camera to acquire droplet information therefrom.

The control module may be configured to detect, from the captured image, a shadow region of the droplet caused by the first light, by detecting a first boundary line based on a preset first threshold value, detect, from the captured image, a droplet region caused by the second light, by detecting a second boundary line based on a preset second threshold value, and measure the droplet information based on the detected shadow region and the detected droplet region.

The droplet information may include a position of the droplet and a volume of the droplet.

The first optical characteristic and the second optical characteristic may include at least one of luminance and color.

The first light source module may be configured to change the first optical characteristic, and the second light source module may be configured to change the second optical characteristic.

The control module may be configured to check a luminance difference between the shadow region identified based on the first light of the first light source module and the droplet region identified based on the second light of the second light source module. When the checked luminance difference is less than a designated reference value, the control module may change at least one of the first optical characteristic of the first light and the second optical characteristic of the second light so that the luminance difference is equal to or greater than the reference value.

The control module may control the first light source module and the second light source module to illuminate the droplet with the first light and the second light simultaneously to obtain a droplet image, and may analyze the obtained droplet image to acquire the droplet information therefrom.

The control module may be configured to control the first light source module to illuminate the droplet with the first light, and control the camera to photograph a droplet being illuminated with the first light to obtain a first image. After obtaining the first image, the control module may control the second light source module to illuminate the droplet with the second light, and control the camera to photograph the droplet being illuminated with the second light to obtain a second image. The control module may analyze the first image and the second image to acquire the droplet information therefrom.

The control module may generate a droplet image by integrating the first image and the second image together, and may analyze the generated droplet image to acquire the droplet information therefrom.

A method for measuring droplet information of a droplet information measuring device includes illuminating a droplet ejected onto a surface of a substrate from an inkjet printing device with first light and second light simultaneously or sequentially. A camera is used to photograph the droplet being illuminated by at least one of the first light and the second light from above the droplet. At least one image photographed by the camera is analyzed to acquire droplet information related to the droplet. The first light has a first optical characteristic and is emitted in an oblique direction with respect to the surface of the substrate. The second light has a second optical characteristic that is different from the first optical characteristic and is emitted in a direction perpendicular to the surface of the substrate.

The step of acquiring droplet information may include detecting a shadow region of the droplet caused by the first light from the captured image, by detecting a first boundary line based on a preset first threshold value, detecting a droplet region caused by the second light from the captured image, by detecting a second boundary line based on a preset second threshold value, and measuring the droplet information based on the detected shadow region and the detected droplet region.

The droplet information may include a position of the droplet and a volume of the droplet.

The first optical characteristic and the second optical characteristic may include at least one of luminance and color.

The method may further include checking a luminance difference between the shadow region identified based on the first light and the droplet region identified based on the second light, and when the checked luminance difference is less than a designated reference value, changing at least one of the first optical characteristic of the first light and the second optical characteristic of the second light so that the luminance difference is equal to or greater than the reference value.

The step of acquiring droplet information may include photographing a droplet being illuminated with the first light and the second light simultaneously by the camera, when the first light and the second light are simultaneously emitted, to obtain a droplet image, and analyzing the obtained droplet image to acquire the droplet information therefrom.

The step of acquiring droplet information may include controlling the camera to photograph a droplet being illuminated with the first light to obtain a first image, after obtaining the first image, photographing a droplet being illuminated with the second light by the camera to obtain a second image, and analyzing the obtained first image and the obtained second image to acquire the droplet information therefrom.

The step of acquiring droplet information may include generating a droplet image by integrating the obtained first image and the obtained second image together, and analyzing the generated droplet image to acquire the droplet information therefrom.

An inkjet printing system according includes an inkjet printing device and a droplet information measuring device configured to measure droplet information of a droplet ejected onto a substrate by the inkjet printing device. The droplet information measuring device includes a first light source module configured to emit a first light having a first optical characteristic, the first light being emitted from the first light source module in an oblique direction with respect to a surface of a substrate on which the droplet is positioned. A second light source module is configured to emit a second light having a second optical characteristic that is different from the first optical characteristic, the second light being emitted from the second source module in a direction perpendicular to the surface of the substrate. A camera is configured to photograph a droplet being illuminated with at least one of the first light and the second light from above the droplet. A control module is configured to analyze at least one image photographed by the camera to acquire droplet information therefrom.

The droplet information measuring device may further include a communication module configured to transmit the acquired droplet information to the inkjet printing device.

The inkjet printing device may control at least one of an ejection position and volume of the droplet based on the droplet information transmitted from the droplet information measuring device.

### BRIEF DESCRIPTION OF THE DRAWINGS

The above and other objects and features of the present disclosure will be more clearly understood from the following detailed description taken in conjunction with the accompanying drawings, in which:

FIG. 1A is a schematic block diagram illustrating a configuration of an inkjet printing system according to an embodiment of the present disclosure;

FIG. 1B is a schematic block diagram illustrating an example of operation of the inkjet printing system according to an embodiment of the present disclosure;

FIG. 2 is a schematic block diagram illustrating the configuration of a droplet information measuring device according to an embodiment of the present disclosure;

FIG. 3 is a side view illustrating an example of measuring droplet information using the droplet information measuring device according to an embodiment of the present disclosure;

FIG. 4A is a side view illustrating an example in which a droplet is illuminated with first light and second light from the droplet information measuring device according to an embodiment of the present disclosure;

FIG. 4B is a plan view illustrating an image captured by photographing the droplet being illuminated with the first light and the second light according to an embodiment of the present disclosure;

FIG. 4C is a plan view and graph illustrating a method for measuring the volume of a droplet using the captured image according to an embodiment of the present disclosure;

FIG. 4D is a side view illustrating an example of detecting a boundary between a droplet and its shadow according to an embodiment of the present disclosure;

FIG. 5 is a flowchart describing a method for measuring droplet information according to an embodiment of the present disclosure; and

FIG. 6 is a flowchart describing a method for measuring droplet information according to an embodiment of the present disclosure.

### DETAILED DESCRIPTION OF THE EMBODIMENTS

Hereinafter, various embodiments of the present disclosure will be described with reference to the accompanying drawings. Specific embodiments of the present disclosure will be illustrated in the drawings and described in the following detailed description related thereto, but are not necessarily intended to limit the various embodiments of the present disclosure to a specific form. For example, the embodiments of the present disclosure described herein may be variously modified within the spirit and scope of the present disclosure.

Embodiments of the present disclosure relate to an apparatus and method for measuring droplet characteristics in an inkjet printing system, enabling precise control over the printing process. Two light sources may be used, each with different optical properties, to illuminate ink droplets deposited on a substrate. The first light is emitted obliquely relative to the substrate surface, generating a shadow that reveals information about the droplet's height and shape, while the second light is projected perpendicularly to highlight the droplet's boundaries and surface region directly. This dual-light arrangement allows the system to capture comprehensive images of the droplet from above using a photographing module, which records how the droplet interacts with both lighting conditions.

Through analysis of the captured images, a control module may extract vital droplet information such as position and volume by distinguishing between the shadow region and the droplet region using preset threshold values. The luminance and color properties of the light sources can be dynamically adjusted to ensure sufficient contrast for accurate detection, especially in varying environmental conditions or substrate types. By calculating parameters like the droplet's major axis length, radius, and the angle of the oblique light, the system can determine the droplet's volume with high precision. This information may then be used for diagnosing nozzle performance and ensuring consistent ink deposition during the printing process.

The integration of this approach into an inkjet printing system may permit real-time monitoring and adjustment of droplet ejection parameters, promoting uniform printing quality across diverse applications such as OLED displays and other advanced electronics manufacturing. When the droplet data indicate irregularities, the system can communicate corrective instructions back to the printer, adjusting factors like ejection position and volume to maintain desired print characteristics. This innovation may enable the production of high-resolution, defect-free printed layers, offering a significant advancement in the precision and reliability of inkjet-based manufacturing technologies.

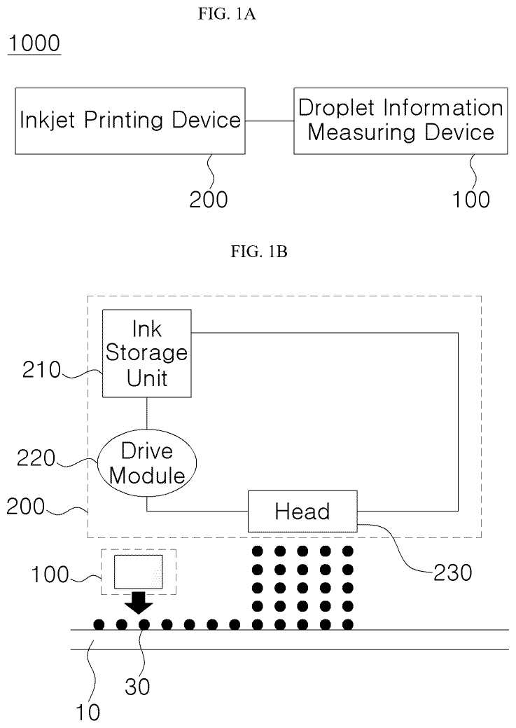

FIG. 1A is a schematic block diagram illustrating the configuration of an inkjet printing system according to an embodiment of the present disclosure, and FIG. 1B is a schematic block diagram illustrating an example of operation of the inkjet printing system according to an embodiment of the present disclosure.

Referring to FIGS. 1A and 1i, an inkjet printing system 1000, according to an embodiment of the present disclosure, may include a droplet information measuring device 100 and an inkjet printing device 200.

The inkjet printing device 200 may spray (or eject) ink (e.g., organic or inorganic electroluminescent (EL) materials) onto a substrate 10 (e.g., a display panel (or a display device)). For example, the inkjet printing device 200 may spray ink onto the substrate 10 in a specific amount and/or in a specific pattern, either sequentially or in parallel, through a head 230.

According to an embodiment, the inkjet printing device 200 may include an ink storage unit 210, a drive module 220 and the head 230.

The head 230 may eject ink. For example, the head 230 may eject ink through a plurality of nozzles. Here, ink ejected from the head 230 and deposited on the substrate 10 will be referred to as a droplet 30.

The drive module 220 may transfer ink stored in the ink storage unit 210 to the head 230. According to an embodiment, the drive module 220 may be a pump. The ink storage unit 210 may store ink. The ink stored in the ink storage unit 210 may be delivered to the head 230 by the drive module 220, and a portion of the ink may be ejected while the remaining portion may be returned to the ink storage unit 210.

According to an embodiment, the inkjet printing device 200 may further include a control module. The control module may control a plurality of nozzles (e.g., actuators included in the nozzles) provided in the head 230 to eject ink. For example, the control module may receive droplet information measured (or determined) by the droplet information measuring device 100, and may control the ejection position and/or volume of the droplets based on the received droplet information. In addition, the control module may determine and/or monitor an abnormality of each nozzle based on the received droplet information.

Additionally, the inkjet printing device 200 may further include sensors configured to detect the ejection pressure, speed, and/or concentration of the ink, which will be used for control, a valve configured to regulate the ink flow, a pressure regulation module configured to adjust the pressure inside the ink storage unit 210 and the like.

The droplet information measuring device 100 may measure (or determine) information of a droplet 30 (hereinafter, “droplet information”) ejected onto the substrate 10 by the inkjet printing device 200. For example, the droplet information measuring device 100 may be configured to: illuminate the droplet 30 with light from a plurality of light sources having different properties, simultaneously or sequentially, in different directions; capture at least one image by photographing the droplet 30 being illuminated with light from at least one of the plurality of light sources using a camera; and acquire (e.g., measure or determine) droplet information using the obtained image. The droplet information may include the ejection position and volume of the droplet. The configuration and measuring method of the droplet information measuring device 100 will be described below in detail.

It is to be understood that as used herein, the camera is not necessarily limited to an ordinary handheld camera and may be any device equipped for capturing an image. Thus, the camera may be an image sensor or any device incorporating the use of an image sensor, such as a still picture camera, a video camera, or any other form of image capture device including those that include lenses and those that do not, and including those that magnify images and those that do not.

The droplet information measuring device 100 may be integrated (or built) into the inkjet printing device 200.

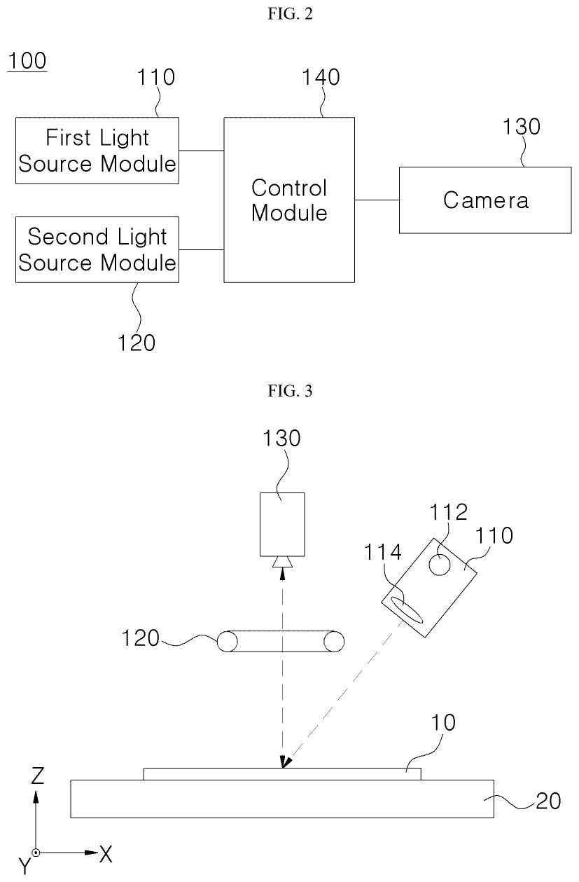

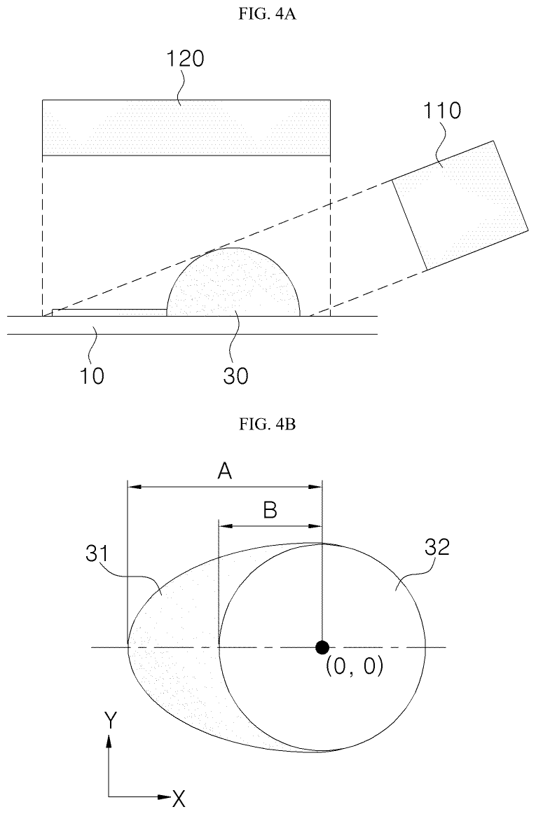

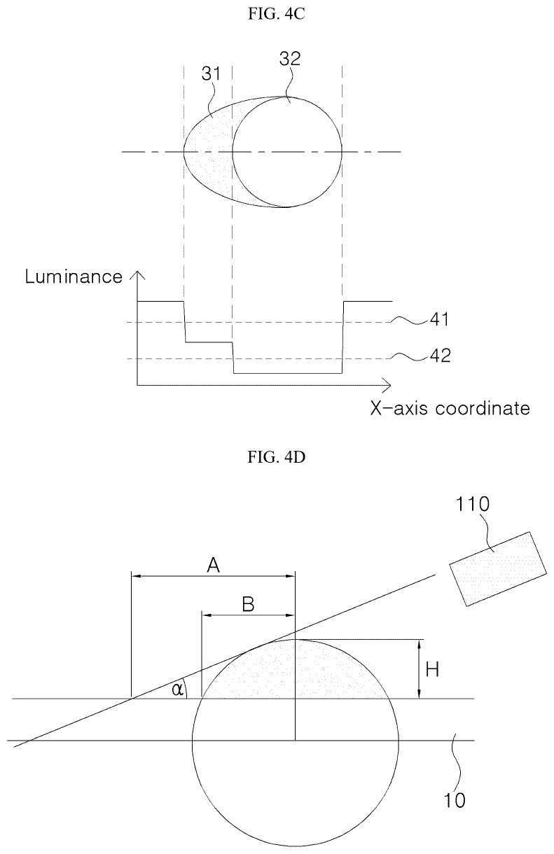

FIG. 2 is a schematic block diagram illustrating the configuration of a droplet information measuring device according to an embodiment of the present disclosure, FIG. 3 is a side view illustrating an example of measuring droplet information using the droplet information measuring device according to an embodiment of the present disclosure, FIG. 4A is a side view illustrating an example in which a droplet is illuminated with first light and second light from the droplet information measuring device according to an embodiment of the present disclosure, FIG. 4B is a plan view illustrating an image captured by photographing the droplet being illuminated with the first light and the second light according to an embodiment of the present disclosure, FIG. 4C is a plan view and graph illustrating a method for measuring the volume of a droplet using the captured image according to an embodiment of the present disclosure, and FIG. 4D is a side view illustrating an example of detecting a boundary between a droplet and its shadow according to an embodiment of the present disclosure.

Referring to FIGS. 2 to 4D, the apparatus for measuring droplet information (hereinafter, the droplet information measuring device) 100, according to an embodiment of the present disclosure, may include a first light source module 110, a second light source module 120, a camera 130, and a control module 140.

The first light source module 110 may illuminate the substrate 10 with a first light. For example, as shown in FIGS. 3 and 4A, the first light source module 110 may emit the first light in an oblique direction (e.g., a direction inclined with respect to the X-axis) relative to the surface of the substrate 10 on which the droplet 30 is positioned. The first light may have a first optical characteristic. For example, the first light may have a first luminance and/or a first color. The first light source module 110 may change the first optical characteristic of the first light under the control of the control module 140, which will be described below.

It is to be understood that as used herein, the optical characteristics may be more than luminance and color and may include properties such as polarization, wavelength spectrum distribution, coherence, etc.

The first light source module 110 may include a light source 112 configured to generate first light and a lens 114 configured to project the generated first light onto a measurement target (e.g., the droplet 30). According to an embodiment, the first light source module 110 may optionally omit the lens 114 and may use a mirror or nothing at all.

The second light source module 120 may illuminate the substrate 10 with a second light. For example, as shown in FIGS. 3 and 4A, the second light source module 120 may emit a second light in a direction perpendicular to the surface of the substrate 10 on which the droplet 30 is positioned (e.g., the Z-axis direction). The second light may have a second optical characteristic that is different from the first optical characteristic. For example, the second light may have a second luminance and/or a second color. The second light source module 120 may change the second optical characteristic of the second light under the control of the control module 140, which will be described below.

The second light source module 120 may include a light source configured to generate second light and a lens configured to project the generated second light onto the measurement target (e.g., the droplet 30). Although FIG. 3 illustrates the second light source module 120 as being separately positioned between the substrate 10 and the camera 130, the second light source module 120 may be integrated into the camera 130. In addition, to avoid obstructing the camera 130, the second light source module 120 may be disposed at a position other than between the substrate 10 and the camera 130, and a transparent reflective mirror that reflects the second light emitted from the second light source module 120 in a direction perpendicular to the substrate 10 may be positioned between the substrate 10 and the camera 130.

The camera 130 may be positioned above the substrate 10. For example, the camera 130 may photograph a droplet (e.g., the droplet 30) being illuminated with at least one of the first light and the second light on the substrate 10. For example, the camera 130 may photograph the droplet 30 while it is simultaneously illuminated with both the first and second lights. Alternatively, the camera 130 may first photograph the droplet 30 illuminated with the first light (or the second light), and then photograph the droplet 30 illuminated with the second light (or the first light).

The control module 140 may analyze at least one image captured by the camera 130 to acquire droplet information related to the droplet 30. For example, the control module 140 may control the first light source module 110 and the second light source module 120 to illuminate the droplet 30 with the first light and the second light simultaneously, control the camera 130 to photograph the droplet 30 being illuminated with the first light and the second light to obtain a droplet image, and analyze the obtained droplet image to acquire the droplet information. As an example, the control module 140 may control the first light source module 110 to illuminate the droplet 30 with the first light, and control the camera 130 to photograph the droplet 30 being illuminated with the first light to obtain a first image. After obtaining the first image, the control module 140 may control the second light source module 120 to illuminate the droplet 30 with the second light, and control the camera 130 to photograph the droplet 30 being illuminated with the second light, thereby obtaining a second image. According to an embodiment, the control module 140 may analyze the first image and the second image independently to acquire the droplet information. As an example, the control module 140 may generate a droplet image by integrating the first image and the second image (e.g., synthesizing a combined image) without independently analyzing the first image and the second image, and may analyze the generated combined droplet image to acquire the droplet information therefrom.

The droplet image captured by the camera 130 may include a shadow region 31 formed (or identified) by the first light and a droplet region 32 formed (or identified) by the second light, as illustrated in FIG. 4B. The control module 140 may detect the shadow region 31 from the droplet image by detecting a first boundary line based on a preset first threshold value 41, and may detect the droplet region 32 from the droplet image by detecting a second boundary line based on a preset second threshold value 42, as illustrated in FIG. 4C.

According to an embodiment, the control module 140 may measure the droplet information based on the detected shadow region 31 and the detected droplet region 32. For example, the control module 140 may measure (or determine) the droplet information based on the shadow region 31 and the droplet region 32, as illustrated in FIG. 4D. For example, the control module 140 may calculate the volume of the droplet 30 using Equations 1 and 2 below.

$$V = \frac{π}{6} H ( 3 {B}^{2} + {H}^{2} ) \qquad 〈 Equation 1 〉$$

$$H = A tan α \qquad 〈 Equation 2 〉$$

In Equations 1 and 2 above, “V” denotes a volume of the droplet, “A” denotes a major axis length of the shadow region 31, “B” denotes a radius of the droplet region 32, “H” denotes a height of the droplet, and “a” denotes an angle between the first light and the substrate 10.

The control module 140 may analyze the droplet region 32 to measure (or determine) the position of the droplet 30. For example, the control module 140 may calculate center coordinates of the droplet region 32 and determine the calculated center coordinates as the position of the droplet 30.

According to an embodiment, the control module 140 may check a luminance difference (e.g., contrast) between the shadow region identified based on the first light of the first light source module 110 and the droplet region identified based on the second light of the second light source module 120, and if the checked luminance difference is less than a designated reference value, may change at least one of the first optical characteristic of the first light and the second optical characteristic of the second light so that the luminance difference is equal to or greater than the reference value.

According to an embodiment, the control module 140 may control a transport means (e.g., carrier, stage, etc.) (20) on which the substrate 10 is mounted to move the substrate 10 and may continuously measure droplet information on the printed droplets.

The droplet information measuring device 100 may further include a wired communication module or a wireless communication module configured to transmit (e.g., send) the droplet information to the inkjet printing device 200. The inkjet printing device 200, which has received the droplet information, may control the ejection position and/or volume of the droplets based on the droplet information. In addition, when a problem occurs in measuring the droplet information, the droplet information measuring device 100 may provide an alarm to a user in various ways. For example, the droplet information measuring device may request a designated external device (e.g., a manager's portable terminal) to provide a visual alarm (e.g., displaying a warning message, blinking a designated light source, etc.), an auditory alarm (e.g., playing a designated sound effect), a tactile alarm (e.g., generating a vibration in a designated pattern), etc.

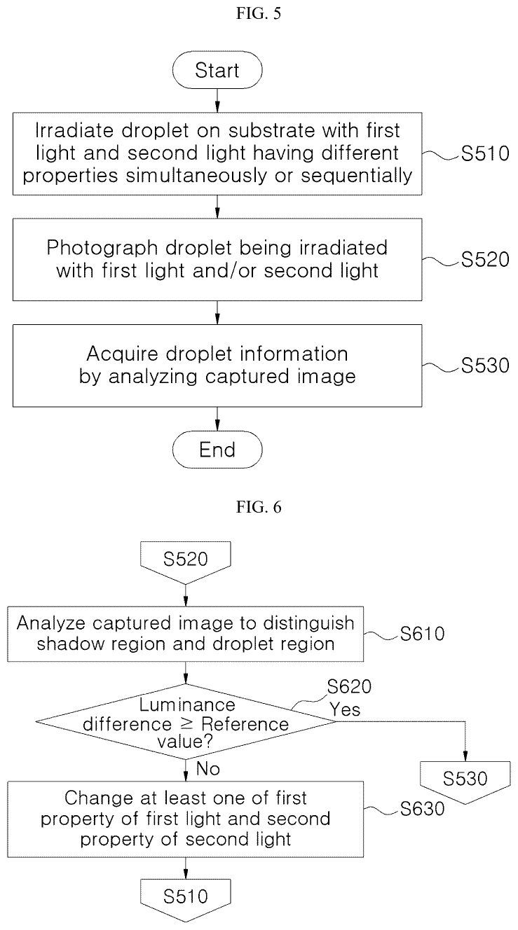

FIG. 5 is a flowchart describing a method for measuring droplet information according to an embodiment of the present disclosure.

Referring to FIG. 5, the method for measuring droplet information according to an embodiment of the present disclosure (hereinafter, the measuring method) may include a step (S510) of illuminating a droplet on the substrate with first light and second light having different properties simultaneously or sequentially. For example, the droplet information measuring device (e.g., the control module 140) may control the first light source module 110 to emit a first light having a first optical characteristic in the oblique direction with respect to the surface of the substrate, and may control the second light source module 120 to emit a second light having a second optical characteristic in the direction perpendicular to the surface of the substrate.

According to an embodiment, the measuring method may include a step (S520) of photographing a droplet being illuminated with the first light and/or the second light. For example, in the case of an embodiment where the first light and the second light are simultaneously illuminated, the droplet information measuring device (e.g., the control module 140) may control the camera 130 to photograph the droplet being simultaneously illuminated with both the first and second lights. In the case of an embodiment where the first light and the second light are sequentially illuminated, the droplet information measuring device (e.g., the control module 140) may activate the first light source module 110 to illuminate the droplet with the first light, control the camera 130 to photograph the droplet being illuminated with the first light, deactivate the first light source module 110 after completing the photographing of the droplet being illuminated with the first light, activate the second light source module 120 to illuminate the droplet with the second light, and control the camera 130 to photograph the droplet being illuminated with the second light.

According to an embodiment, the measuring method may acquire droplet information by analyzing the captured image. For example, the droplet information measuring device (e.g., the control module 140) may detect a shadow region of the droplet caused by the first light, by detecting a first boundary line based on a preset first threshold value from the captured image, detect a droplet region caused by the second light, by detecting a second boundary line based on a preset second threshold value, and acquire droplet information based on the detected shadow region and the detected droplet region. The method of acquiring the droplet information has been described above with reference to FIGS. 2 to 4D, and to the extent that an element is not described in detail with respect to this figure, it may be understood that the element is at least similar to a corresponding element that has been described elsewhere within the present disclosure.

The measuring method may further include a step of transmitting the acquired droplet information to the inkjet printing device that has ejected ink on the substrate. In addition, when a problem occurs in measuring the droplet information, the measuring method may further include an operation of providing an alarm to the user in various ways. For example, the droplet information measuring device may request a designated external device (e.g., a manager's portable terminal) to provide a visual alarm (e.g., displaying a warning message, blinking a designated light source, etc.), an auditory alarm (e.g., playing a designated sound effect), a tactile alarm (e.g., generating a vibration in a designated pattern), etc.

FIG. 6 is a flowchart describing a method for measuring droplet information according to an embodiment of the present disclosure.

Referring to FIG. 6, the method for measuring droplet information according to an embodiment of the present disclosure (hereinafter, the measuring method) may further include operations for changing properties of the first light and the second light. For example, the measuring method may further include steps S610 to S630 between the steps S520 and S530 of FIG. 5.

According to an embodiment, after performing the step S520 of FIG. 5, the measuring method may perform a step (S610) of analyzing the captured image to distinguish the shadow region and the droplet region. For example, the droplet information measuring device (e.g., the control module 140) may distinguish the shadow region 31 and the droplet region 32 based on the first threshold value 41 and the second threshold value 42, as described in FIG. 4C.

According to an embodiment, the measuring method may further include a step (S620) of checking whether a difference (hereinafter, luminance difference) between the luminance (e.g., average luminance) of the identified shadow region 31 and the luminance (e.g., average luminance) of the droplet region 32 is equal to or greater than a designated reference value.

If the luminance difference is equal to or greater than the reference value as a result of the checking in step S620, the measuring method may proceed to step S530 of FIG. 5. If the luminance difference is less than the reference value as a result of the checking in step S620, the measuring method may change at least one of the first optical characteristic of the first light and the second optical characteristic of the second light. This may ensure that the luminance difference is equal to or greater than the reference value. Thereafter, the measuring method may proceed (e.g., return) to step S510 of FIG. 5.

The above-described embodiment may prevent a problem in which the shadow region and the droplet region cannot be clearly distinguished from the droplet image depending on the surrounding environment even when the first light and the second light having different properties are illuminated. Accordingly, the above-described embodiment enables more accurate measurement of droplet information.

Various embodiments of the present disclosure enable droplet information on the droplets ejected by the inkjet printing device to be acquired accurately (or precisely), conveniently, and rapidly. For example, various embodiments of the present disclosure enable droplet information to be accurately (or precisely), conveniently, and rapidly acquired by illuminating the droplets with the first light and the second light having different properties simultaneously.

Various embodiments of the present disclosure may provide uniform printing. For example, various embodiments of the present disclosure may provide uniform printing by accurately measuring droplet information and controlling the ejection position and/or volume based on the measured droplet information.

Various embodiments of the present disclosure and the terms used herein do not necessarily limit the technical characteristics described in the present disclosure to specific embodiments, but may be interpreted to include various modifications, equivalents, or substitutions of the embodiments. With regard to the description of the drawings, similar or related components may be denoted by similar reference numerals. It is to be understood that a singular form of a noun corresponding to an item may include one or a plurality of the things, unless the relevant context clearly indicates otherwise. As used herein, each of phrases such as “A or B,” “at least one of A and B,” “at least one of A or B,” “A, B or C,” “at least one of A, B and C,” and “at least one of A, B or C” may include any one, or all possible combinations of these items enumerated together in the corresponding one of the phrases. As used herein, the terms such as “1st” and “2nd,” or “first” and “second” may be used to simply distinguish the corresponding component from another component, and does not necessarily limit the corresponding components in other aspects (e.g., an importance or order). It is to be understood that if a component (e.g., a first component) is referred to as “bonded to” or “connected to” another component (e.g., a second component), with or without the term “operatively” or “communicatively,” it means that the component may be bonded to the other component directly (e.g., by wire), wirelessly, or via a third component.

The term “module” used in various embodiments of the present disclosure may include a unit implemented in hardware, software or firmware, and for example, may be used interchangeably with the terms such as logic, a logic block, a part, or a circuit. The module may be a part integrally formed therewith, or a minimum unit of the part or a portion thereof which performs one or more functions. For example, according to an embodiment, the module may be implemented in a form of an application-specific integrated circuit (ASIC).

Various embodiments of the present disclosure may be implemented by software (e.g., a program) including one or more instructions stored in a storage medium (e.g., an internal memory or an external memory) readable by a machine. For example, a processor of the machine (e.g., the control module) may call, among one or more instructions stored in the storage medium, at least one instruction, and may execute the instruction. This allows at least one function to be performed according to the called at least one instruction. The one or more instructions may include a code that is made by a compiler or a code that may be executed by an interpreter. The storage medium that may be read by a device may be provided in a form of a non-transitory storage medium. Here, the ‘non-transitory storage medium’ means that the storage medium is a tangible device and does not include a signal (e.g., an electromagnetic wave), and with regard to the term, a case, in which data are semi-permanently stored in the storage medium, and a case, in which data are temporarily stored in the storage medium, are not distinguished.

According to an embodiment, the methods according to various embodiments of the present disclosure may be provided to be included in a computer program product. The computer program product may be traded between a seller and a purchaser. The computer program product may be distributed in a form of a storage medium that may be read by a device (e.g., a compact disk read only memory (CD-ROM)) or may be distributed (e.g., downloaded or uploaded) through an application store or directly or online between two user devices. In the online distribution, at least a portion of the computer program product may be at least temporarily stored in a storage medium, such as a server of a manufacturer, a server of an application store, or a memory of a relay server, which may be read by a device, or temporarily generated.

According to various embodiments, each component or element (e.g., a module or program) of the above-described components or elements may include one or a plurality of entities, and some of the plurality of entities may be disposed to other components while being separated. According to various embodiments, among the above-described components, one or more components or operations thereof may be omitted or one or more other components or operations thereof may be added to the components. Alternatively or additionally, the plurality of components (e.g., the modules or programs) may be integrated into one component. In this case, the integrated components may perform one or more functions of each component of the plurality of components in a way that they are the same as or similar to the functions performed by the corresponding components among the plurality of components before the integration. According to various embodiments, operations performed by the modules, programs, or other components may be executed sequentially, in parallel, repeatedly, or heuristically, one or more operations may be executed in another sequence or omitted, or one or more other operations may be added thereto.

What is claimed is:

1. An apparatus for measuring droplet information, comprising:
a first light source module configured to emit a first light having a first optical characteristic, the first light being emitted from the first light source module in an oblique direction with respect to a surface of a substrate on which a droplet is positioned;
a second light source module configured to emit a second light having a second optical characteristic that is different from the first optical characteristic, the second light being emitted from the second light source module in a direction perpendicular to the surface of the substrate;
a camera configured to photograph a droplet that is illuminated with at least one of the first light and the second light, from above the droplet; and
a control module configured to analyze at least one image photographed by the camera to acquire droplet information therefrom.

2. The apparatus according to claim 1, wherein the control module is configured to:
detect, from the photograph of the droplet, a shadow region of the droplet caused by the first light, by detecting a first boundary line based on a preset first threshold value;
detect, from the photograph of the droplet, a droplet region caused by the second light, by detecting a second boundary line based on a preset second threshold value; and
measure the droplet information based on the detected shadow region and the detected droplet region.

3. The apparatus according to claim 1, wherein the droplet information comprises a position of the droplet and a volume of the droplet.

4. The apparatus according to claim 1, wherein the first optical characteristic and the second optical characteristic comprise at least one of luminance and color.

5. The apparatus according to claim 1, wherein the first light source module is configured to change the first optical characteristic, and
the second light source module is configured to change the second optical characteristic.

6. The apparatus according to claim 2, wherein the control module is configured to:
check a luminance difference between the shadow region identified based on the first light of the first light source module and the droplet region identified based on the second light of the second light source module; and
when the checked luminance difference is less than a designated reference value, change at least one of the first optical characteristic of the first light and the second optical characteristic of the second light so that the luminance difference is equal to or greater than the designated reference value.

7. The apparatus according to claim 1, wherein the control module controls the first light source module and the second light source module to illuminate the droplet with the first light and the second light simultaneously to obtain a droplet image, and analyzes the obtained droplet image to acquire the droplet information therefrom.

8. The apparatus according to claim 1, wherein the control module is configured to:
control the first light source module to illuminate the droplet with the first light, and control the camera to photograph a droplet being illuminated with the first light to obtain a first image;
after obtaining the first image, control the second light source module to illuminate the droplet with the second light, and control the camera to photograph the droplet being illuminated with the second light to obtain a second image; and
analyze the first image and the second image to acquire the droplet information therefrom.

9. The apparatus according to claim 8, wherein the control module generates a droplet image by integrating the first image and the second image together, and analyzes the generated droplet image to acquire the droplet information therefrom.

10. A method for measuring droplet information of a droplet information measuring device, comprising:
illuminating a droplet ejected onto a surface of a substrate from an inkjet printing device with first light and second light simultaneously or sequentially;
photographing, by a camera, the droplet being illuminated by at least one of the first light and the second light from above the droplet; and
analyzing at least one image photographed by the camera to acquire droplet information related to the droplet,
wherein the first light has a first optical characteristic and is emitted in an oblique direction with respect to the surface of the substrate, and
wherein the second light has a second optical characteristic different from the first optical characteristic and is emitted in a direction perpendicular to the surface of the substrate.

11. The method according to claim 10, wherein the step of acquiring droplet information comprises:
detecting a shadow region of the droplet caused by the first light from the photograph of the droplet, by detecting a first boundary line based on a preset first threshold value;
detecting a droplet region caused by the second light from the photograph of the droplet, by detecting a second boundary line based on a preset second threshold value; and
measuring the droplet information based on the detected shadow region and the detected droplet region.

12. The method according to claim 10, wherein the droplet information comprises a position of the droplet and a volume of the droplet.

13. The method according to claim 10, wherein the first optical characteristic and the second optical characteristic comprise at least one of luminance and color.

14. The method according to claim 11, further comprising:
checking a luminance difference between the shadow region identified based on the first light and the droplet region identified based on the second light; and
when the checked luminance difference is less than a designated reference value, changing at least one of the first optical characteristic of the first light and the second optical characteristic of the second light so that the luminance difference is equal to or greater than the reference value.

15. The method according to claim 10, wherein the step of acquiring droplet information comprises:
photographing a droplet being illuminated with the first light and the second light simultaneously by the camera, when the first light and the second light are simultaneously emitted, to obtain a droplet image; and
analyzing the photograph of the droplet to acquire the droplet information therefrom.

16. The method according to claim 10, wherein the step of acquiring droplet information comprises:
controlling the camera to photograph a droplet being illuminated with the first light to obtain a first photograph;
after obtaining the first image, photographing a droplet being illuminated with the second light by the camera to obtain a second photograph; and
analyzing the obtained first photograph and the obtained second photograph to acquire the droplet information therefrom.

17. The method according to claim 16, wherein the step of acquiring droplet information comprises generating a droplet image by integrating the obtained first photograph and the obtained second photograph with each other, and analyzing the generated droplet image to acquire the droplet information therefrom.

18. An inkjet printing system, comprising:
an inkjet printing device; and
a droplet information measuring device configured to measure droplet information of a droplet ejected onto a substrate by the inkjet printing device,
wherein the droplet information measuring device comprises:
a first light source module configured to emit a first light having a first optical characteristic, the first light being emitted from the first light source module in an oblique direction with respect to a surface of a substrate on which the droplet is positioned;
a second light source module configured to emit a second light having a second optical characteristic that is different from the first optical characteristic, the second light being emitted from the second light source module in a direction perpendicular to the surface of the substrate;
a camera configured to photograph the droplet being illuminated with at least one of the first light and the second light from above the droplet; and
a control module configured to analyze at least one image photographed by the camera to acquire droplet information therefrom.

19. The inkjet printing system according to claim 18, wherein the droplet information measuring device further comprises a communication module configured to transmit the acquired droplet information to the inkjet printing device.

20. The inkjet printing system according to claim 19, wherein the inkjet printing device is configured to control at least one of an ejection position and volume of the droplet based on the droplet information transmitted from the droplet information measuring device.
